(19) United States
(12) Patent Application Publication
(10) Pub. No.: US 2025/0197703 A1
(43) Pub. Date: Jun. 19, 2025

(54) Chemical Mechanical Planarization Using Amino-Polyorganosiloxane-Coated Abrasives

(71) Applicant: Versum Materials US, LLC, Tempe, AZ (US)

(72) Inventors: Gerhard Jonschker, Heppenheim (DE); Rene Lutz, Heppenheim (DE)

(21) Appl. No.: 18/846,321

(22) PCT Filed: Mar. 16, 2023
(86) PCT No.: PCT/US2023/064594

§ 371 Date: Sep. 12, 2024

Related U.S. Application Data
(60) Provisional application No. 63/269,585, filed on Mar. 18, 2022.

(51) Int. Cl. C09K 3/14; B24B 37/04; H01L 21/321

(52) U.S. Cl. CPC C09K 3/1436; C09K 3/1463; H01L 21/3212; B24B 37/04

(57) ABSTRACT

Chemical mechanical planarization (CMP) polishing compositions, methods and systems using a stable colloidal abrasive particle dispersion are provided. The abrasive particles in the dispersion are amino-polyorganosiloxane-coated abrasive particles. The amino-polyorganosiloxane-coated abrasive particles have an amino functional polyorganosiloxane shell having a thickness of 0.1 nm to 10 nm, or 0.5 to 5 nm. The amino-polyorganosiloxane-coated abrasive particles have low silanol density and positive charge at acidic low pH range.

### CROSS REFERENCE TO RELATED PATENT APPLICATIONS

The application claims the benefit of priority under 35 U.S.C. § 119(e) to earlier filed U.S. patent application Ser. No. 63/269,585 filed on Mar. 18, 2022, which is entirely incorporated herein by reference.

### BACKGROUND OF THE INVENTION

This invention relates to chemical mechanical planarization (CMP) compositions, chemical mechanical planarization (CMP) methods, and chemical mechanical planarization (CMP) systems.

More specifically, chemical mechanical planarization (CMP) polishing compositions, methods and systems using a stable colloidal abrasive particle dispersion are provided. The abrasive particles in the dispersion are amino-polyorganosiloxane-coated abrasive particles. The amino-polyorganosiloxane-coated abrasive particles have an amino functional polyorganosiloxane shell. The amino-polyorganosiloxane-coated abrasive particles have low silanol density and positive charge at acidic low pH range

In the semiconductor industry, chemical mechanical planarization (CMP) is a well-known technology applied in fabricating advanced photonic, microelectromechanical, and micro-electronic materials and devices, such as semiconductor wafers. CMP polishing is an important step for recovering a selected material and/or planarizing the structure.

CMP utilizes the interplay of chemical and mechanical action to achieve the planarity of the to-be-polished surfaces. Chemical action is provided by a chemical composition, also referred to as CMP slurry or CMP formulation. Mechanical action is majorly carried out by a polishing pad which is typically pressed onto the to-be-polished surface and mounted on a moving platen. The movement of the platen is usually linear, rotational or orbital.

In a typical CMP process step, a rotating wafer holder brings the to-be-polished wafer in contact with a polishing pad. The CMP composition is usually applied between the to-be-polished wafer and the polishing pad.

CMP composition typically comprises abrasive (usually colloidal particles) in aqueous solution.

Without being bound by theory, it is believed that for achieving a stable colloidal abrasive particle dispersion, it is desirable to have the abrasive particles with a very high charge density and zeta potential. It is believed that the charge density on the abrasive particles can be a major contributor to composition performance in addition to providing repulsive forces to stabilize the colloidal abrasive particles.

Aminosilane has been used to modify the abrasive particles to have high charge density and zeta potential.

U.S. Pat. No. 9,028,572 B2 discloses a way to achieve abrasive particles with a charge density and zeta potential through the particle surface treatment with a compound selected from the group consisting of quaternary aminosilane compounds, dipodal aminosilane compounds, and combinations thereof.

It is known, however, that addition of large amounts of aminosilanes tend to destabilize colloidal abrasive particle dispersion and lead to bad performance. Thus, only colloidal abrasive particle dispersion with very low aminosilane loadings (e.g. <1 wt. % per g abrasive) are available. Thus, the performance from the CMP compositions using such colloidal abrasive particle dispersion is limited.

Hence, it should be readily apparent from the foregoing that there remains a need within the art for stable colloidal aminosilane modified abrasive particle dispersion having higher aminosilane loadings to achieve a higher charge density and zeta potential. There is also a continuous need for CMP compositions, methods, and systems that using the stable colloidal amino-polyorganosiloxane-coated abrasive particle dispersion to provide improved performance.

The present invention provides such improved CMP polishing compositions, methods and systems. These and other advantages of the invention, as well as additional inventive features, will be apparent from the description of the invention provided herein.

### SUMMARY OF THE INVENTION

The present invention provides a stable colloidal abrasive particle dispersion, such as stable colloidal amino-polyorganosiloxane-coated silica abrasive particles dispersion having a high charge density.

The CMP compositions, methods, and systems using the stable colloidal amino-polyorganosiloxane-coated abrasive particle dispersion are also provided. The amino-polyorganosiloxane-coated abrasive refers to the abrasive particle surfaces are completely coated or covered with aminofunctional polyorganosiloxane.

Specifically, the CMP compositions using the stable colloidal amino-polyorganosiloxane-coated abrasive particle dispersion show a high removal rate of tungsten (W), excellent selectivity (e.g. W:PECVD TEOS or W:SiNₓ) and performance for chemical mechanical planarization a tungsten surface (that is, W CMP), especially at acidic low pH range.

In one aspect, there is provided stable colloidal amino-polyorganosiloxane-coated abrasive particle dispersion, wherein surface of the amino-polyorganosiloxane-coated abrasive particle has an aminofunctional polyorganosiloxane shell; and a silanol density of <60%, or <50% SiOH/Si atom measured by using ²⁹Si-NMR spectroscopy; and the amino-polyorganosiloxane-coated abrasive particles have a positive charge of >15, >25, or >35 mV.

In another aspect, there is provided a method of making colloidally stable dispersion of amino-polyorganosiloxane-coated abrasive, comprising the steps of:
a. providing aminosilane having a general formula of:

(AₓB_{y}Si)_{z}—R; (I)
wherein x and y each independent is 1 or 2 with X+Y=3, and z is 1 or 2
A is a hydrolysable group such as an alkoxy group selected from the group consisting of methoxy, and ethoxy;
B is a non-hydrolyzable group having no amino group such as alkyl group having 1-6 carbon atoms, and phenyl;
and
R is a non-hydrolyzable group selected from the group consisting of at least one of aryl or alkyl group containing at least one amino group which can be primary, secondary, tertiary, and quaternary amino group;
b. providing colloidal base abrasive particle dispersion wherein the base abrasive particles have reactive groups on their surfaces;
c. adding the aminosilane to the colloidal base abrasive particle dispersion;
d. forming the amino-polyorganosiloxane-coated abrasive particle by interacting aminosilane, its dimers, oligomers, and amino-polyorganosiloxane (liner or cyclic) formed through the interactions among the aminosilane with the reactive groups on the surface of the base abrasive particle to form an aminofunctional polyorganosiloxane shell on the surface of the base abrasive;
wherein
the aminofunctional polyorganosiloxane shell has a thickness of 0.1 nm to 10 nm, or 0.5 to 5 nm; and covers or coats the entire surface of the base abrasive particle;
the amino-polyorganosiloxane-coated abrasive particle has a silanol density of <60%, or <50% SiOH/Si atom; a positive charge of >15, >25, or >35 mV, and a surface charge density or potential charge carrier density of 0.012 to 1.0, 0.04 to 0.8, 0.06 to 0.6, or 0.08 to 0.5 millimole/gram (mmol/g) of silica.

The colloidal base abrasive particle dispersion contains base abrasive particles which can be any suitable abrasive particles having reactive groups on their surfaces. The reactive groups are capable of forming covalent bonds with the aminosilane, its dimers, oligomers, and polymers (liner or cyclic) as disclose above. Preferred abrasive particles comprise Si—OH groups on the surfaces.

R is preferred to be alkyl group containing at least one amino group such as aminomethylene group, an aminoethylene group, an aminopropylene group, an aminoisopropylene group, and an aminobutylene group.

The aminosilanes include but are not limited to methyl or ethyl-substituted-derivatives.

Specifically, the aminosilanes include but are not limited to n-(2-aminoethyl)-3-aminoisobutylmethyldimethoxysilane, n-(2-aminoethyl)-3-aminoisobutyldimethylmethoxysilane, (phenylaminomethyl)methyldimethoxysilane, n-(2-aminoethyl)-3-aminopropylmethyldimethoxysilane, n-(2-aminoethyl)-3-aminopropylmethyldiethoxysilane, 3-(n,n-dimethylaminopropyl)aminopropylmethyldimethoxysilane, 3-aminopropyldiisopropylethoxysilane, 3-aminopropylmethyldiethoxysilane, 4-amino-3,3-dimethylbutylmethyldimethoxysilane, n,n-dimethyl-3-aminopropylmethyldimethoxysilane, n-methylaminopropylmethyldimethoxysilane, 3-aminopropyldimethylmethoxysilane, (phenylaminomethyl)methyldimethoxysilane, bis(methyldimethoxysilylpropyl)-n-methylamine, 4-aminobutyldimethylmethoxysilane, and (4-aminobutyl) methyldiethoxysilane.

The amount of aminosilane is >1, 2, or 3.0; and <20, 15, or 10 weight % per g abrasive.

In some embodiments, the step a of the method described above can provide at least one of co-reactant silane in addition of aminosilane.

A co-reactant silane includes but is not limited to (1)alkoxysilanes and organically modified alkoxysilanes with at least one and maximum two non-hydrolyzable substituent on the Si atom, either inert or carrying functional groups, either aliphatic, or aromatic or cycloaliphatic; such as methyl-, ethyl-, propyl-, or phenyl-group; (2)alkoxysilanes, such as methoxysilanes, ethoxysilanes, propoxysilanes and the like; preferably tetraethyl orthosilicate (TEOS), tetramethyl orthosilicate (TMOS), methyltriethoxysilane (MTEOS), trimethylmethoxysilane (MTMOS), or dimethyldimethoxysilane; or monomers (preferred) and preformed oligomers; (3)silanes with other hydrolysable groups like oximatosilanes, chlorosilanes, silazanes, and oligosilazanes.

The mixing ratio of amount of the aminosilanes vs the amount of the co-reactant used (the amount ratio) is >1:99, >1:50, 1:40, 1:30, 1:20, or >1:10; such as 1:9.

In yet another aspect, there is provided a CMP polishing composition comprises:
stable colloidal amino-polyorganosiloxane-coated abrasive particle dispersion disclosed above; and
water-soluble solvent;
wherein
the composition has a pH of 2 to 10, 2 to 8, 2 to 6, 2 to 5, 2 to 4, or 2 to 3.

The water-soluble solvent includes but is not limited to deionized (DI) water, distilled water, and alcoholic organic solvents.

The CMP polishing composition can optionally comprise at least one of:
organic and inorganic salt as colloidal stabilizer;
acid/base buffer agent;
biocide;
oxidizer;
catalyst;
corrosion inhibitor;
organic polymers as erosion, dishing and corrosion reducer; wherein example polymers include but are not limited to hydrophilic polymers, polymers with organic functional groups like —OH, —NR₁R₂R₃R₄ (with R₁₋₄ being independently either H, alkyl, aryl), CN, ester, amide, halogen, ether, inorganic polymers for like mono-metal- or mixed-metal polymetalhydroxide clusters, polyanions, polycations, especially those containing al, ce, zr, fe as metal ions;
surface-active molecules/oligomers/polymers like cationic-, anionic- or nonionic surfactants and polymers which attach by either physical adsorption, ionic or covalent bonding.

In another aspect, there is provided a method of chemical mechanical polishing (CMP) a substrate having at least one surface comprising tungsten using the chemical mechanical polishing (CMP) composition described above.

The substrate having at least one surface comprising tungsten further comprises silicon dioxide polished silicon oxide films which can be Chemical vapor deposition (CVD), Plasma Enhance CVD (PECVD), High Density Deposition CVD(HDP), or spin on silicon oxide films.

The removal selectivity of W:SiO₂ is greater than 30, preferably greater than 50, 80, 100, 120, or 140.

### BRIEF DESCRIPTION OF SEVERAL VIEWS OF THE DRAWINGS

FIG. 1 depicts the zeta potential (mV) as a function of the amount of aminosilane charge carriers (in mmol/g silica) on the surface of the amino-polyorganosiloxane-coated abrasive particles at pH of 2.5

### DETAILED DESCRIPTION OF THE INVENTION

This invention relates to the Chemical mechanical polishing (CMP) composition (also known as slurry or formulation), methods, and systems using a stable colloidal amino-polyorganosiloxane-coated abrasive particle dispersion wherein the amino-polyorganosiloxane-coated abrasive refers to the abrasive particle having a surface completely coated or covered by an aminofunctional polyorganosiloxane shell. The aminofunctional polyorganosiloxane shell has a thickness of 0.1 nm to 10 nm, or 0.5 to 5 nm. The amino-polyorganosiloxane-coated abrasive particles have high surface charge density or potential charge carrier density of 0.012 to 1.0, 0.04 to 0.8, 0.06 to 0.6, or 0.08 to 0.5 millimole/gram (mmol/g) of silica.
and zeta potential, and low silanol density of <60%, or <50% SiOH/Si atom (measured by using ²⁹Si-NMR spectroscopy). The amino-polyorganosiloxane-coated abrasive particles have a positive charge of >15, >25, or >35 mV.

A colloidal amino-polyorganosiloxane-coated abrasive particle dispersion refers to amino-polyorganosiloxane-coated abrasive particles (usually has at least one dimension ranging from 1 nm to 500 nm) dispersed in a solvent comprising water.

The term “polyorganosiloxane” refers to polymers consisting of a silicon-oxygen backbone with organic alkyl (typically methyl) group(s) attached to silicon atom(s). While the term “polysiloxane” refers to polymers consisting of a silicon-oxygen with no alkyl (methyl) group(s) attached to the silicon atom. Examples are polysiloxanes formed by for example, tetraethyl orthosilicate (TEOS).

For achieving excellent performance, such as removal rates and selectivity, it is desirable to have the abrasive particles having a very high charge density and zeta potential. It is believed that the charge density on the abrasive particles can be a major contributor to CMP composition performance in addition to providing repulsive forces to stabilize the colloidal abrasive particles in the CMP composition.

For example, a higher charge density is believed to contribute to low SiO₂ removal rates which is a sought-after feature of abrasives for chemical mechanical planarization a tungsten surface, especially in the acidic pH region for W CMP compositions.

Thus, it is desirable to attach a large/high amount of amino groups on the surface of abrasives which then react at the low pH with positively charged ammonium groups.

It is known however, that addition of large amounts of aminosilanes tend to destabilize colloidal abrasive particle dispersions and lead to bad removal rates and selectivity.

For example, aminosilane modification of silica is known to be difficult and often leads to aggregation and gelation if too much aminosilane is used, especially if not processed carefully.

Aminosilane as a modifier, especially as a surface modifier is meant to convert isolated silanol groups to siloxane on the surface of abrasive particles. The amount of aminosilane to be used is usually kept as low as possible just to reach a high enough zeta potential. Thus typically aminosilane loadings are very low (e.g. <1 weight or wt. % per silica abrasive). There are free silanol groups still left after the low aminosilane loadings are used.

Further, it is believed that the aminosilane modified abrasive particles need to exhibit a low silanol content for W CMP where excellent selectivity (e.g. W:PECVD TEOS or W:SiNₓ) is needed. This is due to the factor that the silanol groups can interact with SiO₂ and SiN coatings and affecting their removal rates, and thus potentially reduce the selectivity of W CMP.

The present invention has demonstrated that, many problems which are associated with achieving high aminosilanes loadings in colloidal abrasive particle dispersion can be mitigated if using an aminofunctional silanes (aminosilanes) having (1) at least one aminofunctional moiety, including —NH₂, —NR₁H, —NR₂R₃, (R_{2,3} being aliphatic, aromatic, with or without further functional groups), protonated cationic ammonium-functional moieties such as —N⁺H₃ or —N⁺R₂R₃H; (2) at least one Si moiety, can be bidentate (like e.g. bis-propyl-dimethoxymethylsilyl-amine) or oligomeric; and (3) at least one hydrolysable group and maximum 2 hydrolysable groups on the (each) silicon atom.

In another aspect, there is provided a method of making colloidally stable dispersion of amino-polyorganosiloxane-coated abrasive particles, comprising the steps of:
a. providing an aminosilane having a general formula of:

(AₓB_{y}Si)_{z}—R; (I)
wherein x and y each independent is 1 or 2 with X+Y=3, and z is 1 or 2
A is a hydrolysable group such as an alkoxy group selected from the group consisting of methoxy, and ethoxy;
B is a non-hydrolyzable group having no aminogroup such as alkyl group having 1-6 carbon atoms, and phenyl;
and
R is a non-hydrolyzable group selected from the group consisting of at least one of aryl or alkyl group containing at least one amino group which can be primary, secondary, tertiary, and quaternary amino group;
b. providing colloidal base abrasive particle dispersion wherein the base abrasive particles have reactive groups on their surfaces;
c. adding the aminosilane to the colloidal base abrasive particle dispersion;
d. forming the amino-polyorganosiloxane-coated abrasive particle by interacting aminosilane, its dimers, oligomers, and amino-polyorganosiloxane (liner or cyclic) formed through the interactions among the aminosilane with the reactive groups on the surface of the base abrasive particle to form an aminofunctional polyorganosiloxane shell on the surface of the base abrasive;
wherein
the aminofunctional polyorganosiloxane shell has a thickness of 0.1 nm to 10 nm, or 0.5 to 5 nm; and covers or coats the entire surface of the base abrasive particle.

The aminofunctional polyorganosiloxane shell has a thickness of 0.1 nm to 10 nm, or 0.5 to 5 nm. The amino-polyorganosiloxane-coated abrasive particle has a surface charge density or potential charge carrier density of 0.012 to 1.0, 0.04 to 0.8, 0.06 to 0.6, or 0.08 to 0.5 millimole/gram (mmol/g) of silica, a silanol density of <60%, or <50% SiOH/Si atom; and a positive charge of >15, >25, or >35 mV.

The aminosilanes shown in formula (I) are most cross linkable aminosilanes.

The colloidal base abrasive particle dispersion contains base abrasive particles which can be any suitable abrasive particles having reactive groups on their surfaces. The reactive groups are capable of forming covalent bonds with the aminosilane, its dimers, oligomers, and polymers (liner or cyclic) as disclose above. Preferred abrasive particles comprise Si—OH groups on the surfaces.

R is preferred to be alkyl group containing at least one amino group such as aminomethylene group, an aminoethylene group, an aminopropylene group, an aminoisopropylene group, and an aminobutylene group.

The aminosilanes include but are not limited to methyl or ethyl-substituted-derivatives.

Specifically, the aminosilanes include but are not limited to n-(2-aminoethyl)-3-aminoisobutylmethyldimethoxysilane, n-(2-aminoethyl)-3-aminoisobutyldimethylmethoxysilane, (phenylaminomethyl)methyldimethoxysilane, n-(2-aminoethyl)-3-aminopropylmethyldimethoxysilane, n-(2-aminoethyl)-3-aminopropylmethyldiethoxysilane, 3-(n,n-dimethylaminopropyl)aminopropylmethyldimethoxysilane, 3-aminopropyldiisopropylethoxysilane, 3-aminopropylmethyldiethoxysilane, 4-amino-3,3-dimethylbutylmethyldimethoxysilane, n,n-dimethyl-3-aminopropylmethyldimethoxysilane, n-methylaminopropylmethyldimethoxysilane, 3-aminopropyldimethylmethoxysilane, (phenylaminomethyl)methyldimethoxysilane, bis(methyldimethoxysilylpropyl)-n-methylamine, 4-aminobutyldimethylmethoxysilane, and (4-aminobutyl) methyldiethoxysilane.

The amount of aminosilane is >1, 2, or 3.0 and <20, 15, or 10 weight % per g abrasive. For example, if colloidal silica is used as the base abrasive particle, then the amount of aminosilane is >1, 2, or 3.0 and <20, 15, or 10 weight % per g silica.

In some embodiments, the step a of the method described above can further provide at least one of co-reactant silane in addition of providing aminosilane.

When y=2 and z=1, a co-reactant silane is needed.

A co-reactant silane includes but is not limited to (1)alkoxysilanes and organically modified alkoxysilanes with at least one and maximum two non-hydrolyzable substituents on the Si atom, either inert or carrying functional groups, either aliphatic, or aromatic or cycloaliphatic; such as methyl-, ethyl-, propyl-, or phenyl-group; (2)alkoxysilanes, such as methoxysilanes, ethoxysilanes, propoxysilanes and the like; preferably tetraethyl orthosilicate (TEOS), tetramethyl orthosilicate (TMOS), methyltriethoxysilane (MTEOS), trimethylmethoxysilane (MTMOS), or dimethyldimethoxysilane; or monomers (preferred) and preformed oligomers; (3)silanes with other hydrolysable groups like oximatosilanes, chlorosilanes, silazanes, and oligosilazanes.

Among the co-reactant, tetraethyl orthosilicate (TEOS), and tetramethyl orthosilicate (TMOS) are network forming silanes; and methyltriethoxysilane (MTEOS), trimethylmethoxysilane (MTMOS), and dimethyldimethoxysilane are network modifying silanes. The co-reactant silane acts together with the aminosilanes, its dimers, oligomers, and polymers (liner or cyclic) to form the aminofunctional polyorganosiloxane shell on the surfaces of the base abrasive particles.

The aminosilanes and the co-reactant silane can be pre-reacted to form dimers, trimers or oligomers prior to being brought into contact with the base abrasive particles.

The mixing ratio of aminosilane and the co-reactant silane determines the mechanical and chemical properties of the polyorganosiloxane.

The mixing ratio of amount of the aminosilanes vs the amount of the co-reactant used (the amount ratio) is >1:99, 1:50, 1:40, 1:30, 1:20, or >1:10 such as 1:9.

In yet another aspect, there is provided a CMP polishing composition comprises:
stable colloidal amino-polyorganosiloxane-coated abrasive particle dispersion disclosed above; and
water-soluble solvent;
wherein
the composition has a pH of 2 to 10, 2 to 8, 2 to 6, 2 to 5, 2 to 4, or 2 to 3.

The water-soluble solvent includes but is not limited to deionized (DI) water, distilled water, and alcoholic organic solvents.

The CMP polishing composition can optionally comprise at least one of:
organic and inorganic salt as colloidal stabilizer;
acid/base buffer agent;
biocide;
oxidizer;
catalyst;
corrosion inhibitor;
organic polymers as erosion, dishing and corrosion reducer; wherein example polymers include but are not limited to hydrophilic polymers, polymers with organic functional groups like —OH, —NR₁R₂R₃R₄ (with R₁₋₄ being independently either H, alkyl, aryl), CN—, ester, amide, halogen, ether,
inorganic polymers for like mono-metal- or mixed-metal polymetalhydroxide clusters, polyanions, polycations, especially those containing Al, Ce, Zr, Fe as metal ions;
surface-active molecules/oligomers/polymers like cationic-, anionic- or nonionic surfactants and polymers which attach by either physical adsorption, ionic or covalent bonding.

The aminosilane can be added with high load to the colloidal base abrasive particle dispersion.

Generally, base abrasive particles can be any suitable CMP abrasive particles as long as the abrasive particles have reactive groups on their surfaces which are capable of forming a covalent bond with such as an aminosilane as disclose above.

Preferred abrasive particles comprise Si—OH groups on the surfaces, such as silica.

The base abrasive particles can have any shapes: spherically or non-spherically shaped such as elongated and/or branched, the base abrasive particles can partially be aggregated. Elongated shaped is preferred.

The base abrasive particles can be colloidal or fumed silica, alumina, ceria, homogenous or gradient or core/shell particles (like silica on alumina), composite particles (such as ceria coated silica particles), or combinations thereof. Colloidal silica and fumed silica are preferred. The base colloidal silica can be synthesized by wet chemistry, thermally produced (e.g. fumed, fused, etc.), doped (e.g. with Al, Ce ions), using mixed metal oxides (e.g. alumosilicates, zirkoniumsilicates).

The base abrasive particles can have a mean particle size (MPS) (for aggregated or non-spherically shaped particles) from 5-500 nm, 10-400 nm, 15-200 nm, or 25-150 nm measured by Dynamic Light Scattering (DLS).

Process to make amino-polyorganosiloxane-coated abrasive particles starts with adding a sufficient amount of cross linkable aminosilane which has a general formula (I) as shown above into the base abrasive particle dispersion.

The total amount of reactive groups of the used aminosilane or together with co-reactant silanes (if they are added) needs to exceed the number of accessible silanol groups on the surfaces of the abrasive particles.

Without being bound by theory, it is believed that the reactions include (1) the reaction between the aminosilanes and the base abrasive particles. More specifically, part of the aminosilanes react all their alkoxy-reactive sites with Si—OH groups on the surfaces of base abrasive particles to convert/shield/endcap Si—OH groups; and (2) the reactions among the excessive part of aminosilanes themselves to form monomers, oligomers and/or polymers of polyaminoorganosiloxanes. Part of the amino-polyorganosiloxanes will have multiple chemical bonds to the base abrasive particles and part of amino-polyorganosiloxanes will be cross-linked to other amino-polyorganosiloxanes to form a shell on the top of the base abrasive particles. Additionally monomers, oligomers and/or polymers of the used aminosilanes can also be present in the dispersion of the amino-polyorganosiloxane-coated abrasive particles either freely without any type of bond to the abrasive particles or associated with the abrasive particles via non-covalent bonds.

These free, unbound aminopolysiloxanes seem to play a decisive role in the performance of amino-polyorganosiloxane-coated abrasive particles regarding the W-removal rate.

The amino-polyorganosiloxane-coated abrasive particles have a core-shell structure with the base abrasive particles as core and an aminopolyorganosiloxanes shell. The thickness of the shell is from 0.1-10 nm, preferably 0.5-5 nm.

Without being bound by theory, it is believed that the amino-polyorganosiloxane-coated abrasive particles having such core-shell structure contain much more aminosilanes than the other abrasive particles known in the state of the art.

Please note that the aminosilanes having the general formula (I) are different than the well-known and typically used trialkoxy-aminofunctional silanes. The aminosilanes having the general formula (I) are mono- or dialkoxysilanes having a non-hydrolyzable group (or groups) without an aminogroup. Typically used trialkoxy-aminofunctional silanes do not have the non-hydrolyzable group (or groups) without an aminogroup in addition of not been mono- or dialkoxysilanes.

Surprisingly it has been discovered that abrasives with identical amounts of unbound polysiloxanes show dramatically different W-RR when the known aminofunctional trialkoxysilanes are used instead of the mono- or dialkoxysilanes. The W-RR of the inventive abrasives can be as much as 30-50 times higher than that of the known abrasives with trialkoxy-aminosilane.

Thus, it seems that the presence of non-hydrolyzable group(s) on the Si atom may play a role to understand the described effects. The non-hydrolyzable group(s) on the Si atom may affect the hydrolysis and condensation speed of the silanes, their adsorption on the abrasive particle surfaces and the structure of the dimers/oligomers which are generated either on the particle surface or in solution.

The amino-polyorganosiloxane-coated abrasive particles are new particles and not just an aminosilane-modified abrasive particles as it is known in the art.

The aminofunctional polyorganosiloxane shell on the surface of the base abrasive particles has its own chemical and mechanical properties that are different than the base or core abrasive particles. Thus, the amino-polyorganosiloxane-coated abrasive particles are hybrid core/shell abrasive particles.

The amino-groups in the amino-polyorganosiloxane shell are potential charge carriers depending on the pH of the dispersion medium.

In an acidic dispersion medium (preferred), these amino groups are protonated to form an ammonium ion and carry a positive charge. This positive charge is responsible for a desirably high zeta potential at these preferred low pH (e.g. pH 2.5) which is a prerequisite for a colloidally stable abrasive dispersion.

The zeta potential (mv) of aminosilane- and amino-polyorganosiloxane shell coated abrasive particles can be monitored as a function of the charge carrier amount (mmol/g silica).

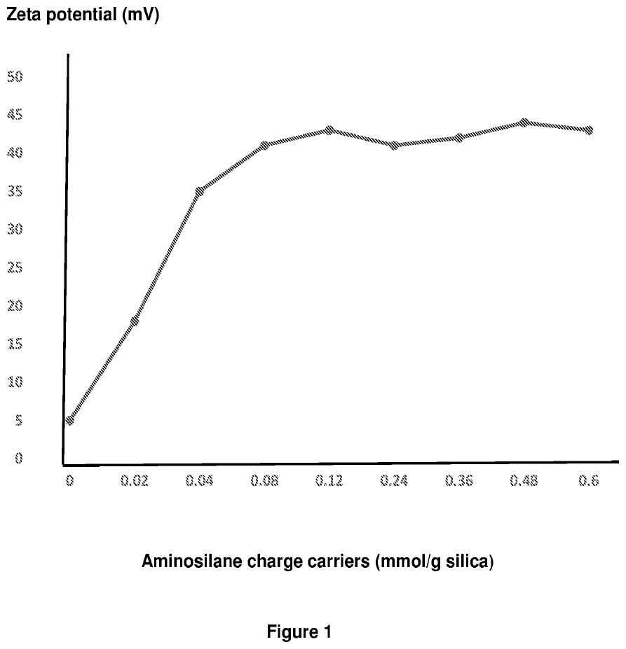

FIG. 1 illustrates a chart of measured zeta potential values of 90 nm SiO₂ particles modified with increasing amounts of aminosilane (aminomethyldimethoxysilane), which were in mmol/g silica at pH of 2.5.

It's clearly shown that even tiny amounts of charge carriers (amino groups) can lead to a sufficiently high zeta potential of the abrasives and that a further excess of charge carriers does not necessarily increase the zeta potential further, but rather leads to a plateau in zeta potential.

The state of the art does not teach that an excess of charge carriers above the amount needed for reaching a plateau in zeta potential gives any advantage to colloidal stability or CMP performance.

Therefore, it was highly surprising to discover that when the amino-polyorganosiloxane shell contains an excess of potential charge carriers (amino groups), much more than needed to maintain a high zeta potential (>+25 mV @pH 2.5) for minimum colloidal stability, the abrasives exhibit the documented high CMP performance of removal rates and selectivity combined with excellent colloidal stability.

Without wanting to be bound by a theory, this high charge carrier density on the surface of the abrasive may contribute to the combination of excellent selectivity and high removal rates of the inventive abrasives.

However, this effect of the high charge carrier density shows only with the inventive amino-polyorganosiloxane shell wherein amino functional polyorganosiloxane contains alkyl group having 1-6 carbon atoms and not for state-of-the-art aminosilane surface modifications without these alkyl groups.

Again, the amino-polyorganosiloxane-coated abrasive particles are not just an aminosilane-modified abrasive particles as it is known in the art.

In another aspect, there is provided a method of chemical mechanical polishing (CMP) a substrate having at least one surface comprising tungsten using the chemical mechanical polishing (CMP) composition described above.

In yet another aspect, there is provided a system of chemical mechanical polishing (CMP) a substrate having at least one surface comprising tungsten using the chemical mechanical polishing (CMP) composition described above.

The substrate having at least one surface comprising tungsten further comprises silicon dioxide polished silicon oxide films which can be Chemical vapor deposition (CVD), Plasma Enhance CVD (PECVD), High Density Deposition CVD(HDP), or spin on silicon oxide films.

The removal selectivity of W:SiO₂ is greater than 30, preferably greater than 50, 80, 100, 120, or 140.

The following examples further illustrate the invention but, of course, should not be construed as in any way limiting its scope.

### CMP Methodology

In the examples presented below, CMP experiments were run using the procedures and experimental conditions given below.

### Glossary

### Parameters

### General

Å or A: angstrom(s)—a unit of length
BP: back pressure, in psi units
CMP: chemical mechanical planarization=chemical mechanical polishing
CS: carrier speed
DF: Down force: pressure applied during CMP, units: psi
min: minute(s)
ml: milliliter(s)
mV: millivolt(s)
psi: pounds per square inch
PS: platen rotational speed of polishing tool, in rpm (revolution(s) per minute)
SF: composition flow, ml/min
TEOS: tetraethyl orthosilicate
Wt. %: weight percentage (of a listed component)
W:TEOS Selectivity: (removal rate of W)/(removal rate of TEOS)
HDP: high density plasma deposited TEOS
TEOS or HDP Removal Rates: Measured TEOS or HDP removal rate at a given down pressure.

### Metrology

Films were measured with a ResMap CDE, model 168, manufactured by Creative Design Engineering, Inc, 20565 Alves Dr., Cupertino, CA, 95014. The ResMap tool is a four-point probe sheet resistance tool. Forty-nine-point diameter scan at 5 mm edge exclusion for film was taken.

### CMP Tool

The CMP tool that was used is a 200 mm Mirra, or 300 mm Reflexion manufactured by Applied Materials, 3050 Boweres Avenue, Santa Clara, California, 95054. An IC1000 pad supplied by DOW, Inc, 451 Bellevue Rd., Newark, DE 19713 was used on platen 1 for blanket and pattern wafer studies.

The IK4250UH pad or other pad was broken in by conditioning the pad for 18 mins. At 7 lbs. down force on the conditioner. To qualify the tool settings and the pad break-in two tungsten monitors and two TEOS monitors were polished with Versum® ST12305 composition, supplied by Versum Materials Inc. at baseline conditions.

All polishing data in the following examples was generated on a Mirra polisher using an IC 1010 pad at a polishing downforce of 2.5 psi.

### Wafers

Polishing experiments were conducted using PECVD or LPCVD or HD TEOS wafers. These blanket wafers were purchased from Silicon Valley Microelectronics, 2985 Kifer Rd., Santa Clara, CA 95051.

### 1. Abrasive Modification Experiments

### A. COMPARATIVE EXAMPLES

### Example 1 Using 3-aminopropyltrimethoxysilane

Peanut-shaped colloidal silica particles IDISIL® KE40 were purchased from Evonik. The mean particle size was measured with DLS to be 53 nm.

Peanut-shaped colloidal silica particles were surface-modified with 3-aminopropyltrimethoxysilane in this example.

In a 4-neck 250 ml round shaped flask equipped with magnetic stirrer, a water-borne dispersion of peanut-shaped SiO₂ nanoparticles (126.26 g; 0.42 mol SiO₂, mean particle size 53 nm, pH 4.1), which had been treated before with Amberlite IRN-150 ion exchanger, was stirred at room temperature.

In a 100 ml round flask, nitric acid 65% (3.2 ml; 45.84 mmol) and methanol (31.22 ml; 0.77 mol) were mixed.

3-aminopropyltrimethoxysilane, 97% (2.69 ml; 15.28 mmol) was then added and the mixture was shaken by hand for 5 seconds and then added quickly to the dispersion of SiO₂ particles. Stirring the mixture continuously for 1 hour at room temperature and then 2 hours at 70° C. to form the reaction mixture.

100 ml deionized water was added to the reaction mixture and the resulting dispersion was concentrated on a rotary evaporator until the solid content reached about 20 weight %.

Yield: 104.1 g, solid content 23.5%, pH 0.99

Particle size: 53 nm (DLS), PDI 0.063, zeta potential: 34.8 mV

### Example 2 Using 3-aminopropyltrimethoxysilane

Elongated-shaped nanoparticles as disclosed U.S. Appl. No. 63/177,539 filed on Apr. 21, 2021, were used.

Elongated-shaped colloidal silica particles were surface-modified with 3-aminopropyltrimethoxysilane in this example.

The same process steps as used and described in the Comparative Example 1 were used this example.

In a 4-neck 1000 ml round shaped flask equipped with magnetic stirrer, a dispersion of elongated-shaped nanoparticles was given (384.60 g; 0.42 mol SiO₂, mean particle size: 90.2 (DLS) a PDI of 0.044 and a pH of 4.0) which had been ion exchanged with Amberlite IRN-150, was stirred at room temperature.

In a 100 ml round flask, nitric acid 65% (2.52 ml; 36.09 mmol) and methanol (41.37 ml; 1.02 mol) were mixed. 3-aminopropyltrimethoxy silane (2.1 ml; 12.03 mmol) was then added and the mixture was shaken by hand for 5 seconds and then added quickly to the dispersion of SiO₂ particles. Stirring the mixture continuously for 1 hour at room temperature and then 2 hours at 70° C. to form the reaction mixture.

200 ml deionized water were added to the reaction mixture and the resulting dispersion was concentrated on a rotary evaporator until the solid content reached about 20 weight %.

Yield: 112.3 g, solid content: 20.6%, pH 1.03

Particle size: 87.9 nm (DLS), PDI: 0.041, zeta potential: 41.2 mV

### Example 3 Using 2-aminoethyl-3-aminopropyl-trimethoxysilane

Elongated-shaped nanoparticles as disclosed U.S. Appl. No. 63/177,539 filed on Apr. 21, 2021, were used.

Elongated-shaped colloidal silica particles were surface-modified with 2-aminoethyl-3-aminopropyl-trimethoxysilane in this example.

The same process steps as used and described in the Comparative Example 1 were used this example.

In a 4-neck 250 ml round shaped flask equipped with magnetic stirrer, a water-borne dispersion of elongated-shaped SiO₂ nanoparticles (126.26 g; 0.42 mol SiO₂, mean particle size 53 nm, pH 4.1), which had been treated before with Amberlite IRN-150 ion exchanger, was stirred at room temperature.

In a 100 ml round flask, nitric acid 65% (6.39 ml; 91.68 mmol) and methanol (31.22 ml; 0.77 mol) were mixed. 2-aminoethyl-3-aminopropyltrimethoxysilane (3.30 ml; 15.28 mmol) was the added and the mixture was shaken by hand for 5 seconds and then added quickly to the dispersion of SiO₂ particles. Stirring the mixture continuously for 1 hour at room temperature and then 2 hours at 70° C. to form the reaction mixture.

100 ml deionized water were added to the reaction mixture and the resulting dispersion was concentrated on a rotary evaporator until the solid content reached about 20 weight %.

Yield: 95.0 g, solid content 17.2%, pH 0.91

Particle size: 53.1 nm (DLS) PDI: 0.058, zeta potential: 36.9 mV.

### Example 4 Using 3-aminopropyltrimethoxysilane

Elongated-shaped nanoparticles as disclosed U.S. Appl. No. 63/177,539 filed on Apr. 21, 2021, were used.

Elongated-shaped colloidal silica particles were surface-modified with 3-aminopropyltrimethoxysilane in this example.

The same process steps as used and described in the Comparative Example 1 were used this example.

In a 4-neck 1000 ml round shaped flask equipped with magnetic stirrer, a dispersion of elongated-shaped nanoparticles was given (384.60 g; 0.42 mol SiO₂, mean particle size: 90.2 (DLS) a PDI of 0.044 and a pH of 4.0) which had been ion exchanged with Amberlite IRN-150, was stirred at room temperature.

In a 100 ml round flask, nitric acid 65% (0.157 ml; 2.25 mmol) and methanol (41.37 ml; 1.02 mol) were mixed. 3-aminopropyltrimethoxy silane (0.13 ml; 0.752 mmol) was then added and the mixture was shaken by hand for 5 seconds and then added quickly to the dispersion of SiO₂ particles. Stirring the mixture continuously for 1 hour at room temperature and then 2 hours at 70° C. to form the reaction mixture.

200 ml deionized water were added to the reaction mixture and the resulting dispersion was concentrated on a rotary evaporator until the solid content reached about 20 weight %.

Yield: 110.1 g, solid content: 20.1%, pH 1.13

Particle size: 85.7 nm (DLS), PDI: 0.039, zetapotential: 36.4 mV

### B. WORKING EXAMPLES

### Example 1: Using 3-aminopropyl-methyldimethoxysilane

Same peanut-shaped colloidal silica particles IDISIL® KE40, and the same process steps as used and described in the Comparative Example 1 were used this example.

However, the peanut-shaped colloidal silica particles were surface-modified with 3-aminopropyl-methyldimethoxysilane in this example.

In a 4-neck 250 ml round shaped flask equipped with magnetic stirrer, a water-borne dispersion of elongated-shaped SiO₂ nanoparticles (126.26 g; 0.42 mol SiO₂, mean particle size 53 nm, pH 4.1), which had been treated before with Amberlite IRN-150 ion exchanger, was stirred at room temperature.

In a 100 ml round flask, nitric acid 65% (3.20 ml; 45.84 mmol), and methanol (31.22 ml; 0.77 mol) were mixed. 3-aminopropyl-methyldimethoxysilane (2.63 ml; 15.28 mmol) was then added and the mixture was shaken by hand for 5 seconds and then added quickly to the dispersion of SiO₂ particles. Stirring the mixture continuously for 1 hour at room temperature and then 2 hours at 70° C. to form the reaction mixture.

100 ml deionized water were added to the reaction mixture and the resulting dispersion was concentrated on a rotary evaporator until the solid content reached about 20 weight %.

Yield: 110.2 g, solid content 22.6% pH=1.09

Particle size: 53.7 nm (DLS), PDI: 0.078, zeta potential: 34.9 mV

### Example 2: Using 3-aminopropyl-dimethylmethoxysilane

Same peanut-shaped colloidal silica particles IDISIL® KE40, and the same process steps as used and described in the Comparative Example 1 were used this example.

However, the peanut-shaped colloidal silica particles were surface-modified with 3-aminopropyl-dimethylmethoxysilane in this example.

In a 4-neck 250 ml round shaped flask equipped with magnetic stirrer, a water-borne dispersion of elongated-shaped SiO₂ nanoparticles (126.26 g; 0.42 mol SiO₂, mean particle size 53 nm, pH 4.1) which had been treated before with Amberlite IRN-150 ion exchanger, was stirred at room temperature.

In a 100 ml round flask, nitric acid 65% (3.20 ml; 45.84 mmol) and methanol (31.22 ml; 0.77 mol) were mixed. 3-aminopropyl-dimethylmethoxysilane (2.59 ml; 15.28 mmol) and methyltriethoxysilane (3.06 ml; 15.28 mmol) was then added and the mixture was shaken by hand for 5 seconds and then added quickly to the dispersion of SiO₂ particles. Stirring the mixture continuously for 1 hour at room temperature and then 2 hours at 70° C. to form the reaction mixture.

100 ml deionized water were added to the reaction mixture and the resulting dispersion was concentrated on a rotary evaporator until the solid content reached about 20 weight %.

Yield: 109.3 g, solid content 22.9%, pH 1.07

Particle size: 53 nm (DLS) PDI: 0.060, zeta potential: 34.1 mV.

### Example 3: Using 3-aminopropyl-methyldimethoxysilane

Elongated-shaped nanoparticles as disclosed U.S. Appl. No. 63/177,539 filed on Apr. 21, 2021, were used.

The same process steps as used and described in the Comparative Example 1 were used this example.

However, the peanut-shaped colloidal silica particles were surface-modified with 3-aminopropyl-methyldimethoxysilane in this example.

In a 4-neck 1000 ml round shaped flask equipped with magnetic stirrer, a dispersion of elongated-shaped nanoparticles was given (384.60 g; 0.42 mol SiO₂, particle size: 90.29 (DLS) a PDI of 0.044 and a pH of 4.0) which had been ion exchanged with Amberlite IRN-150 before, was stirred at room temperature.

In a 100 ml round flask, nitric acid 65% (2.52 ml; 36.09 mmol) and methanol (41.37 ml; 1.02 mol) were mixed. 3-aminopropyl-methyldimethoxysilane (2.07 ml; 12.03 mmol) was then added and the mixture was shaken by hand for 5 seconds and then added quickly to the dispersion of SiO₂ particles. Stirring the mixture continuously for 1 hour at room temperature and then 2 hours at 70° C. to form the reaction mixture.

200 ml deionized water were added to the reaction mixture and the resulting dispersion was concentrated on a rotary evaporator until the solid content reached about 20 weight %.

Yield: 107.8 g, solid content: 20.3%, pH=1.03

Particle size: 87.9 nm (DLS), PDI: 0.045 zeta potential: 46.7 mV

### Example 4: Using 3-aminopropyl-dimethylmethoxysilane

Elongated-shaped nanoparticles as disclosed U.S. Appl. No. 63/177,539 filed on Apr. 21, 2021, were used.

The same process steps as used and described in the Comparative Example 1 were used this example.

However, the peanut-shaped colloidal silica particles were surface-modified with 3-aminopropyl-methyldimethoxysilane in this example.

In a 4-neck 1000 ml round shaped flask equipped with magnetic stirrer, a dispersion of elongated-shaped nanoparticles was given (384.60 g; 0.42 mol SiO₂, particle size: 90.29 (DLS) a PDI of 0.044 and a pH of 4.0) which had been ion exchanged with Amberlite IRN-150 before was stirred at room temperature.

In a 100 ml round flask, nitric acid 65% (2.52 ml; 36.09 mmol) and methanol (41.37 ml; 1.02 mol) were mixed. 3-aminopropyl-dimethylmethoxysilane (2.04 ml; 12.03 mmol) and methyltriethoxysilane (2.41 ml; 12.03 mmol) were then added and the mixture was shaken by hand for 5 seconds and then added quickly to the dispersion of SiO₂ particles. Stirring the mixture continuously for 1 hour at room temperature and then 2 hours at 70° C. to form the reaction mixture.

200 ml deionized water were added to the reaction mixture and the resulting dispersion was concentrated on a rotary evaporator until the solid content reached about 20 weight %.

Yield: 112.3 g, solid content: 20.6%, pH 1.03

Particle size: 89.6 nm (DLS), PDI: 0.032, zeta potential: 37.9 mV

### 2. Silanol Density Measurements

Silanol density was measured by ²⁹Si-NMR spectroscopy.

From the deconvoluted spectra the Q¹-Q⁴ signals were quantified (Σ(Q¹, . . . , Q⁴)=100%) and the silanol density was calculated according to the following formula:
Q¹: 3 silanol groups per Si (300%)
Q²: 2 silanol groups per Si (200%)
Q³: 1 silanol group per Si (100%)
Q⁴: 0 silanol groups per Si (0%)

$$Silanol density ( \% silanol per Si atom ) = {Q}^{1 *} 300 + {Q}^{2 *} 200 + {Q}^{3 *} 100$$

The results of silanol density on the surfaces of abrasive particles obtained from Comparative Example 2 and Working Examples 3 and 4 were listed in Table 1.

TABLE 1
Silanol Density

| | Silanol density (% silanol |
|---|---|
| Abrasive | per Si atom) |
| Comparative Example 2 | 64.7% |
| Example 3 | 48.01% |
| Example 4 | 44.7% |

As shown in Table 1, the number of detected silanol groups from the abrasive particles treated with 3-aminopropyl-dimethylmethoxysilane (non-inventive) is significantly higher than from the abrasive particles treated with 3-aminopropyl-methyldimethoxysilane (inventive Example 3), or 3-aminopropyltrialkoxysilane (Inventive Example 4). This could contribute a further explanation for the extraordinary good CMP performance of the inventive abrasives.

### 3. CMP Polishing Experiments

### Removal Rates & Selectivity

The modified SiO₂-dispersions obtained in Abrasive Modification Experiments were used to formulate typical W-CMP slurries. The removal rates (RR) of tungsten wafers and CVD-TEOS (SiO₂) coatings were measured with a Mirra polisher (2.5 psi, IC1010).

TABLE 2
Removal Rates and Selectivity

| | | | Tungsten- | |
|---|---|---|---|---|
| | Tungsten | SiO₂ | to-SiO₂ | |
| | Mean RR | Mean RR | RR- | |
| Abrasive | (A/min) | (A/min) | Selectivity | Description |
| Comparative | 87 | 10 | 9 | 88 nm particle size, 3-aminopropyltrimethoxysilane |
| Example 2 | | | | |
| Example 3 | 1117 | 8 | 140 | 88 nm particle size, 3-aminopropylmethyldimethoxysilane |
| Example 4 | 1311 | 10 | 131 | 88 nm particle size, 3-aminopropyldimethylmethoxysilane |
| Comparative | 88 | 9 | 10 | Idisil KE40, 3-aminopropyltrimethoxysilane |
| Example 1 | | | | |
| Example 1 | 1095 | 9 | 122 | Idisil KE40, 3-aminopropylmethyldimethoxysilane |
| Example 2 | 1268 | 9 | 141 | Idisil KE40, 3-aminopropyldimethylmethoxysilane |
| Comparative | 40 | 9 | 4 | Idisil KE49, 2-aminoethyl-3-aminopropyltrimethoxysilane |
| Example 3 | | | | |

The CMP slurries were disclosed in U.S. Pat. No. 11,111,435 B2, which is entirely incorporated herein by reference.

Polishing results (removal rate and selectivity) were shown in Table 2.

The measured removal rates clearly show the advantage of using the methyl- or dimethyl-derivative compared to the trimethoxysilane. The inventive particles show a 30-fold higher W removal rate and a 35-fold higher selectivity than the comparative example with the commonly used silane, which is a very surprising difference which has never been described before.

### Defectivity Measurements

For defectivity measurements, the abrasive made in Comparative example 4 was used in addition of the abrasives obtained from Working Examples 3 and 4. The total defect rate and the number of scratches were measured (0.13μ threshold, n=3), 2.5 PSI, Mirra, IC1010. The defectivity results were shown in Table 3.

TABLE 3
Defectivity

| | Total | Total |
|---|---|---|
| Abrasive | defects | scratches |
| Comparative example 4 | 2413 | 9 |
| Example 3 | 720 | 3 |
| Example 4 | 1360 | 1 |

Total defects and scratches using abrasives from the inventive working examples were found to be significantly lower than that from Comparative example 4.

The CMP polishing results from the CMP compositions containing stable colloidal amino-polyorganosiloxane-coated abrasive particle dispersion abrasive particles using 3-aminopropyl-methyl-dimethoxysilane or 3-aminopropyl-dimethylmethoxysilane and methyltriethoxysilane (as a co-reactant silane) at high amounts did lead to a surprisingly better performance than a 3-aminopropyl-trimethoxysilane for both removal rates and selectivity.

The CMP polishing results also showed that the CMP compositions using the amino-polyorganosiloxane-coated abrasive particles surprisingly suppressed defects during CMP comparing with the known abrasives of the state of the art made as shown in Comparative example 4.

Without wanting to be bound by a theory, it is believed that the unique properties of the amino-modified polyorganosiloxane shell compared to the simple “surface modified silica” of the benchmark (Comparative example 4) is the decisive factor in reducing the number of defects.

The embodiments of this invention listed above, including the working example, are exemplary of numerous embodiments that may be made of this invention. It is contemplated that numerous other configurations of the process may be used, and the materials used in the process may be elected from numerous materials other than those specifically disclosed.

1. A stable colloidal amino-polyorganosiloxane-coated abrasive particle dispersion,
wherein
the amino-polyorganosiloxane-coated abrasive particle has an aminofunctional polyorganosiloxane shell as its surface; wherein the aminofunctional polyorganosiloxane contains alkyl group having 1-6 carbon atoms.

2. The stable colloidal amino-polyorganosiloxane-coated abrasive particle dispersion of claim 1, wherein the amino-polyorganosiloxane-coated abrasive particle has a silanol density of <60%, or <50% SiOH/Si atom; and a positive charge of >15, or >35 mV.

3. The stable colloidal amino-polyorganosiloxane-coated abrasive particle dispersion of claim 1, wherein the aminofunctional polyorganosiloxane shell has a thickness of 0.1 to 10 nm, or 0.5 to 5 nm.

4. A method of making stable colloidal amino-polyorganosiloxane-coated abrasive particle dispersion comprising:
a. providing aminosilane having a general formula of:
(AₓB_{y}Si)_{z}—R; (I)
wherein x and y each independent is 1 or 2 with x+y=3, and z is 1 or 2;
A is a hydrolysable group selected from the group consisting of methoxy, and ethoxy, and combinations thereof;
B is a non-hydrolyzable group selected from the group consisting of alkyl group having 1-6 carbon atoms, and phenyl-; wherein B has no amino group;
and
3 of 14
R is a non-hydrolyzable group selected from the group consisting of aryl or alkyl group containing at least one amino group which can be primary, secondary, tertiary, or quaternary amino group;
b. providing colloidal base abrasive particle dispersion wherein the base abrasive particle have reactive groups on its surface;
c. adding the aminosilane to the colloidal base abrasive particle dispersion;
d. forming the amino-polyorganosiloxane-coated abrasive particle by interacting aminosilane, its dimers, oligomers, and amino-polyorganosiloxane (liner or cyclic) formed through the interactions among the aminosilane with the reactive groups on the surface of the base abrasive particle to form an aminofunctional polyorganosiloxane shell on the surface of the base abrasive;
wherein
the aminofunctional polyorganosiloxane shell has a thickness of 0.1 nm to 10 nm, or 0.5 to 5 nm; and covers or coats entire surface of the base abrasive particle;
the amino-polyorganosiloxane-coated abrasive particle has a silanol density of <60%, or <50% SiOH/Si atom; and a positive charge of >15, or >35 mV.

5. The method of making stable colloidal amino-polyorganosiloxane-coated abrasive particle dispersion of claim 4, wherein the base abrasive particle is selected from the group consisting of colloidal silica, fumed silica, alumina, ceria, homogenous or gradient or core/shell particles, composite particles and combinations thereof; and the reactive groups on the surface of the base abrasive particle are Si—OH groups.

6. (canceled)

7. The method of making stable colloidal amino-polyorganosiloxane-coated abrasive particle dispersion of claim 4, wherein B in formula (I) is a methyl; R is selected from the group consisting of aminomethylene group, an aminoethylene group, an aminopropylene group, an aminoisopropylene group, an aminobutylene group, aminoethylaminopropyl group, and combinations thereof.

8. (canceled)

9. (canceled)

10. The method of making stable colloidal amino-polyorganosiloxane-coated abrasive particle dispersion of claim 4, wherein the aminosilane is selected from the group consisting of n-(2-aminoethyl)-3-aminoisobutylmethyldimethoxysilane, n-(2-aminoethyl)-3-aminoisobutyldimethylmethoxysilane, (phenylaminomethyl)methyldimethoxysilane, n-(2-aminoethyl)-3-aminopropylmethyldimethoxysilane, n-(2-aminoethyl)-3-aminopropylmethyldiethoxysilane, 3-(n,n-dimethylaminopropyl)aminopropylmethyldimethoxysilane, 3-aminopropyldiisopropylethoxysilane, 3-aminopropylmethyldiethoxysilane, 4-amino-3,3-dimethylbutylmethyldimethoxysilane, n,n-dimethyl-3-aminopropylmethyldimethoxysilane, n-methylaminopropylmethyldimethoxysilane, 3-aminopropyldimethylmethoxysilane, (phenylaminomethyl)methyldimethoxysilane, bis(methyldimethoxysilylpropyl)-n-methylamine, 4-aminobutyldimethylmethoxysilane, (4-aminobutyl) methyldiethoxysilane, and combinations thereof; and
the amount of aminosilane is >1, 2, or 3.0; and <20, 15, or 10 weight % per g abrasive.

11. The method of making stable colloidal amino-polyorganosiloxane-coated abrasive particle dispersion of claim 4, wherein the aminosilane is a methyl-substituted-derivative selected from the group consisting of aminopropyldimethoxymethylsilane, and aminopropyldimethylmethoxysilane; and the amount of aminosilane is >1, 2, or 3.0; and <20, 15, or 10 weight % per g abrasive.

12. The method of making stable colloidal amino-polyorganosiloxane-coated abrasive particle dispersion of claim 4, wherein the aminosilane is (3-aminopropyl)dimethoxymethylsilane; the colloidal base abrasive particles are colloidal silica, and the stable colloidal amino-polyorganosiloxane-coated abrasive particle dispersion is a stable colloidal amino-polyorganosiloxane-coated silica dispersion.

13. (canceled)

14. (canceled)

15. The method of making stable colloidal amino-polyorganosiloxane-coated abrasive particle dispersion of claim 4, wherein the step a. further provide at least one of (a) at least one of co-reactant silane selected from the group consisting of (1) alkoxysilane and organically modified alkoxysilane with at least one and maximum two non-hydrolyzable substituent on the Si atom selected from the group consisting of methyl-, ethyl-, propyl-, and phenyl-group; and (2) silane with hydrolysable group selected from the group consisting of oximatosilanes, chlorosilanes, silazanes, oligosilazanes, and combinations thereof; wherein the reactant silane also interacts with the reactive groups on the surface of the base abrasive particle and aminosilane to form an aminofunctional polyorganosiloxane shell on the surface of the base abrasive particle; and ratio of amount of the aminosilanes vs the amount of the co-reactant silane is >1:99, or >1:30; and (b) at least one alkoxysilane selected from the group consisting of methoxysilanes, ethoxysilanes, propoxysilanes and the like; Preferably tetraethyl orthosilicate (TEOS), tetramethyl orthosilicate (TMOS), methyltriethoxysilane (MTEOS), methyltrimethoxysilane (MTMOS), dimethyldimethoxysilane; monomers of the alkoxysilane, and preformed oligomers of the alkoxysilane; wherein the reactant silane also interacts with the reactive groups on the surface of the base abrasive particle and aminosilane to form an aminofunctional polyorganosiloxane shell on the surface of the base abrasive particle and ratio of amount of the aminosilanes vs the amount of the co-reactant silane is >1:99, or >1:30.

16. (canceled)

17. The method of making stable colloidal amino-polyorganosiloxane-coated abrasive particle dispersion of claim 4, wherein the aminosilane has y=2 and z=1; the step a. further a further provide at least one alkoxysilane selected from the group consisting of methoxysilanes, ethoxysilanes, propoxysilanes and the like; preferably tetraethyl orthosilicate (TEOS), tetramethyl orthosilicate (TMOS), methyltriethoxysilane (MTEOS), methyltrimethoxysilane (MTMOS), dimethyldimethoxysilane; monomers of the alkoxysilane, and preformed oligomers of the alkoxysilane; wherein the reactant silane also interacts with the reactive groups on the surface of the base abrasive particle and aminosilane to form an aminofunctional polyorganosiloxane shell on the surface of the base abrasive particle and ratio of amount of the aminosilanes vs the amount of the co-reactant silane is >1:99, or >1:30.

18. The method of making stable colloidal amino-polyorganosiloxane-coated abrasive particle dispersion of claim 4, wherein the colloidal base abrasive particles are colloidal silica; the aminosilane is (3-aminopropyl)(methoxy)dimethylsilane; the step a further a further provide methyltriethoxysilane; ratio of amount of (3-aminopropyl)(methoxy)dimethylsilane vs amount of methyltriethoxysilane is >1:50, 1:40, or >1:30; and the stable colloidal amino-polyorganosiloxane-coated abrasive particle dispersion is a stable colloidal amino-polyorganosiloxane-coated silica dispersion.

19. A chemical mechanical polishing (CMP) composition comprises:
the stable colloidal amino-polyorganosiloxane-coated abrasive particle dispersion of claim 1;
water-soluble solvent; and
optionally at least one of:
organic and inorganic salt as colloidal stabilizer;
acid/base buffer agent;
biocide;
oxidizer;
catalyst;
corrosion inhibitor;
organic polymers as erosion, dishing and corrosion reducer; wherein example polymers include but are not limited to hydrophilic polymers, polymers with organic functional groups like —OH, —NR₁R₂R₃R₄ (with R₁₋₄ being independently either H, alkyl, aryl), CN—, ester, amide, halogen, ether,
inorganic polymers for like mono-metal- or mixed-metal polymetalhydroxide clusters, Polyanions, Polycations, especially those containing Al, Ce, Zr, Fe as metal ions;
surface-active molecules/oligomers/polymers like cationic-, anionic- or nonionic surfactants and polymers which attach by either physical adsorption, ionic or covalent bonding;
wherein the CMP composition has a pH of 2 to 10, or 2 to 8.

20. A chemical mechanical polishing (CMP) method comprises:
providing a substrate having at least one surface comprising tungsten;
providing a chemical mechanical polishing (CMP) composition comprises:
stable colloidal amino-polyorganosiloxane-coated abrasive particle dispersion of claim 1; and
water-soluble solvent; and
optionally at least one of:
organic and inorganic salt as colloidal stabilizer;
acid/base buffer agent;
biocide;
oxidizer;
catalyst;
corrosion inhibitor;
organic polymers as erosion, dishing and corrosion reducer; wherein example polymers include but are not limited to hydrophilic polymers, polymers with organic functional groups like —OH, —NR₁R₂R₃R₄ (with R₁₋₄ being independently either H, alkyl, aryl), CN—, ester, amide, halogen, ether,
inorganic polymers for like mono-metal- or mixed-metal polymetalhydroxide clusters, Polyanions, Polycations, especially those containing Al, Ce, Zr, Fe as metal ions;
surface-active molecules/oligomers/polymers like cationic-, anionic- or nonionic surfactants and polymers which attach by either physical adsorption, ionic or covalent bonding;
wherein the CMP composition has a pH of 2 to 10, or 2 to 8;
contacting the surface of the semiconductor substrate with the polishing pad and the chemical mechanical polishing composition; and
polishing the least one surface comprising tungsten.

21. The chemical mechanical polishing (CMP) method of claim 20, wherein the surface of the semiconductor substrate further comprises silicon dioxide film; and removal selectivity of W:SiO₂ is greater than 30, or 120.

22. A chemical mechanical polishing (CMP) system comprises:
a polishing pad;
a substrate having at least one surface comprising tungsten;
a chemical mechanical polishing (CMP) composition comprises:
the stable colloidal amino-polyorganosiloxane-coated abrasive particle dispersion of claim 1;
water-soluble solvent; and
optionally at least one of:
organic and inorganic salt as colloidal stabilizer;
acid/base buffer agent;
biocide;
oxidizer;
catalyst;
corrosion inhibitor;
organic polymers as erosion, dishing and corrosion reducer; wherein example polymers include but are not limited to hydrophilic polymers, polymers with organic functional groups like —OH, —NR₁R₂R₃R₄ (with R₁₋₄ being independently either H, alkyl, aryl), CN—, ester, amide, halogen, ether,
inorganic polymers for like mono-metal- or mixed-metal polymetalhydroxide clusters, Polyanions, Polycations, especially those containing Al, Ce, Zr, Fe as metal ions;
surface-active molecules/oligomers/polymers like cationic-, anionic- or nonionic surfactants and polymers which attach by either physical adsorption, ionic or covalent bonding;
wherein the CMP composition has a pH of 2 to 10, or 2 to 8;
wherein the surface of the semiconductor substrate with the polishing pad and the chemical mechanical polishing composition.

23. The chemical mechanical polishing (CMP) system of claim 22, wherein the surface of the semiconductor substrate further comprises silicon dioxide film; and removal selectivity of W:SiO₂ is greater than 50, or 120.

24. The stable colloidal amino-polyorganosiloxane-coated abrasive particle dispersion of claim 1, wherein the stable colloidal amino-polyorganosiloxane-coated abrasive particle dispersion is a stable colloidal amino-polyorganosiloxane-coated silica dispersion.

25. The chemical mechanical polishing (CMP) composition of claim 19, wherein the amino-polyorganosiloxane-coated abrasive particle has a silanol density of <60%, or <50% SiOH/Si atom; and a positive charge of >15, >25, or >35 mV; and the aminofunctional polyorganosiloxane shell of the amino-polyorganosiloxane-coated abrasive particle has a thickness of 0.1 to 10 nm, or 0.5 to 5 nm.

26. The chemical mechanical polishing (CMP) composition of claim 19, wherein the stable colloidal amino-polyorganosiloxane-coated abrasive particle dispersion is a stable colloidal amino-polyorganosiloxane-coated silica dispersion.

27. The chemical mechanical polishing (CMP) system of claim 22, wherein the stable colloidal amino-polyorganosiloxane-coated abrasive particle dispersion is a stable colloidal amino-polyorganosiloxane-coated silica dispersion.

28. A chemical mechanical polishing (CMP) composition comprises:
stable colloidal amino-polyorganosiloxane-coated abrasive particle dispersion of claim 4;
water-soluble solvent; and
optionally at least one of:
organic and inorganic salt as colloidal stabilizer;
acid/base buffer agent;
biocide;
oxidizer;
catalyst;
corrosion inhibitor;
organic polymers as erosion, dishing and corrosion reducer; wherein example polymers include but are not limited to hydrophilic polymers, polymers with organic functional groups like —OH, —NR₁R₂R₃R₄ (with R₁₋₄ being independently either H, alkyl, aryl), CN—, ester, amide, halogen, ether,
inorganic polymers for like mono-metal- or mixed-metal polymetalhydroxide clusters, polyanions, polycations, especially those containing Al, Ce, Zr, Fe as metal ions;
surface-active molecules/oligomers/polymers like cationic-, anionic- or nonionic surfactants and polymers which attach by either physical adsorption, ionic or covalent bonding;
wherein the CMP composition has a pH of 2 to 10, or 2 to 8.

29. The chemical mechanical polishing (CMP) composition of claim 28, wherein the amino-polyorganosiloxane-coated abrasive particle has a silanol density of <60%, or <50% SiOH/Si atom; and a positive charge of >15, >25, or >35 mV; and the aminofunctional polyorganosiloxane shell of the amino-polyorganosiloxane-coated abrasive particle has a thickness of 0.1 to 10 nm, or 0.5 to 5 nm.

30. The chemical mechanical polishing (CMP) composition of claim 28, wherein the stable colloidal amino-polyorganosiloxane-coated abrasive particle dispersion is a stable colloidal amino-polyorganosiloxane-coated silica dispersion.
